(19) United States
(12) Patent Application Publication
(10) Pub. No.: US 2013/0017674 A1
(43) Pub. Date: Jan. 17, 2013

(54) CRYOGENIC SILICON ION-IMPLANTATION AND RECRYSTALLIZATION ANNEALING

(71) Applicant: Hiroshi Itokawa, Malta, NY (US)

(72) Inventor: Hiroshi Itokawa, Malta, NY (US)

(73) Assignee: TOSHIBA AMERICA ELECTRONIC COMPONENTS, INC., Irvine, CA (US)

(21) Appl. No.: 13/181,935

(22) Filed: Jul. 13, 2011

(51) Int. Cl. H01L 21/205; H01L 21/265

(52) U.S. Cl. 438/503; 438/798; 257/E21.102; 257/E21.335

(57) ABSTRACT

Described herein are methods for forming a semiconductor structure. The methods involve forming a doped semiconductor film, amorphizing the doped semiconductor film through ion implantation; and annealing the doped semiconductor film. The ion implantation and the annealing can increase an activation efficiency of the dopant. The ion implantation and the annealing can also reduce a number of crystalline defects in the doped semiconductor film.

### FIELD

Embodiments described herein generally relate to methods for improving dopant activation activity and reducing crystalline defects in doped semiconductor films.

### BACKGROUND

In scaled metal-oxide-semiconductor field-effect transistors (MOSFETs), parasitic series resistance can be reduced through low resistivity source and drain (S/D) formation. However, conventional methods of low resistivity S/D formation suffer from low dopant activation efficiency and/or crystalline defects.

### BRIEF DESCRIPTION OF DRAWINGS

FIG. 1 shows a schematic process flow diagram of a method for improving dopant activation efficiency and reducing crystalline defects in a doped semiconductor film.

FIG. 2 shows a schematic process flow diagram of an example method for improving phosphorous activation efficiency and reducing crystalline defects in a silicon:phosphorous (Si:P) epitaxial grown film.

FIG. 3 shows depth profiles of phosphorous in an Si:P epitaxial grown film that has undergone silicon ion implantation and laser annealing.

FIG. 4 shows electrical characteristics of a Si:P epitaxial grown film that has undergone silicon ion implantation and laser annealing.

FIG. 5 shows a plot of defect concentration for different annealing temperatures.

FIG. 6 shows a schematic illustration of the difference in defect density during ion implantation at different temperatures.

FIG. 7 shows a schematic illustration of the difference in defect density after annealing.

FIG. 8 shows cross sectional transmission electron microscopy images illustrating crystal quality on the surface of Si:P films.

### DETAILED DESCRIPTION

According to one or more aspects, the subject innovation generally relates to semiconductor manufacturing methods and semiconductor devices fabricated according to the semiconductor manufacturing methods. The semiconductor manufacturing methods of the subject innovation can improve dopant activation efficiency and reduce crystalline defects in a doped semiconductor film. The semiconductor manufacturing methods can lead to the formation of a low resistivity S/D and a reduced parasitic series resistance in a scaled MOSFET.

A method of S/D formation is in situ highly doped silicon alloy selective epitaxial growth (SEG) using chemical vapor deposition (CVD). SEG can allow high quality epitaxy grown on different crystallographic planes, such as on both nFET and pFET S/D regions. However, high working temperatures (e.g., greater than about 670 degrees Celsius) utilized in SEG lead to low dopant activation efficiency.

Dopant activation efficiency can be increased through a pseudo SEG process, which can be the combination of a non-selective epitaxy process, such as a non-selective deposition, with a selective process, such as the selective removal of undesirable material. A pseudo SEG process can have a lower operating temperature than traditional SEG (e.g., less than 610 degrees Celsius), which can lead to a high dopant activation efficiency. However, the pseudo SEG process can lead to crystalline defects.

Provided herein is a method that is able to achieve a high dopant activation activity compared to SEG, while minimizing crystalline defects found with pseudo SEG. The methods described herein are performed on a doped semiconductor film. First, the doped semiconductor film undergoes an ion implantation process. The ion implantation can occur in temperatures less than room temperature. For example, the ion implantation can occur in temperatures of about 0 degrees Celsius or less. The ion implantation can also occur in temperatures of about −60 degrees Celsius or less. The ion implantation can be followed by flash annealing the doped semiconductor film (e.g., at a temperature of about 1000 degrees Celsius or more for a time of about 10 milliseconds or less).

The subject innovation is now described with reference to the drawings, wherein like reference numerals are used to refer to like elements throughout. In the following description, for purposes of explanation, numerous specific details are set forth in order to provide a thorough understanding of the subject innovation. It may be evident, however, that the subject innovation may be practiced without these specific details. In other instances, well-known structures and devices are shown in block diagram form in order to facilitate describing the subject innovation.

With respect to any figure or numerical range for a given characteristic, a figure or a parameter from one range may be combined with another figure or a parameter from a different range for the same characteristic to generate a numerical range.

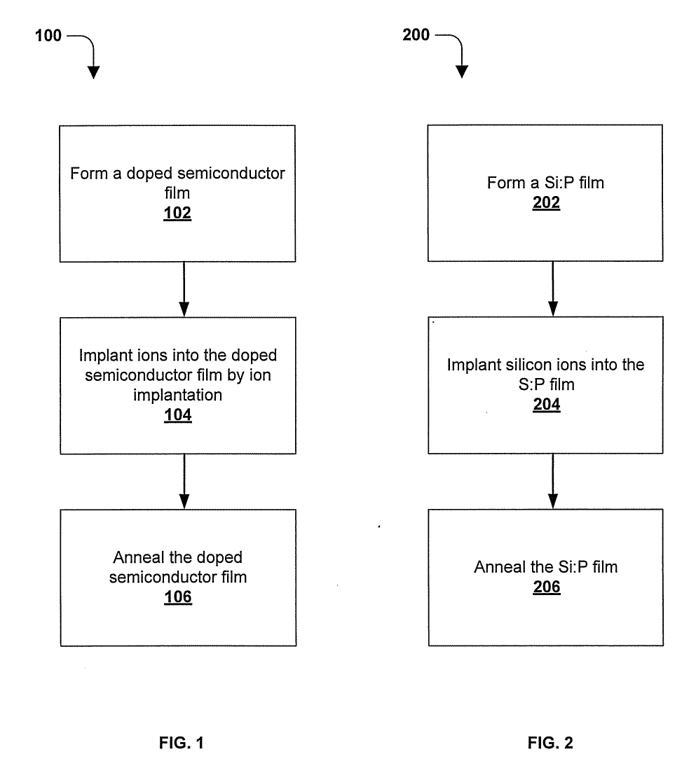

Referring now to FIG. 1, illustrated is a schematic process flow diagram of a method 100 for improving dopant activation activity and reducing crystalline defects in a doped semiconductor film. At element 102, a doped semiconductor film is formed. Any doped semiconducting material, such as silicon and/or germanium, can be utilized in the semiconductor film. Examples of dopants include one or more of phosphorous, boron, arsenic, and the like.

A selective epitaxial growth (SEG) process can be employed to form the doped semiconductor film. The doped semiconductor film can be a monocrystalline film formed on a substrate (e.g., a silicon substrate) according to an in situ SEG process, which can occur in temperatures of about 500 degrees Celsius or more and about 1500 degrees Celsius or less. The SEG process can be used to grow layers of doped silicon on polished sides of silicon wafers, before they are processed into semiconductor devices. The semiconductor film can be an epitaxial film, an epitaxial layer, or the like.

One example of an in situ SEG process that can be utilized to form the doped semiconductor film is a vapor phase epitaxial growth process. The vapor phase epitaxial process can be a silicon vapor phase epitaxy that utilizes silane, dichlorosilane, trichlorosilane, or the like. According to an embodiment, the vapor phase epitaxial process can utilize a dichlorosilane/hydrogen gas mixture. The doped semiconductor film can be doped during deposition by adding impurities to the gas, such as arsine, phosphine, diborane, or the like. The vapor phase epitaxial growth process can occur at a temperature of about 600 degrees Celsius or more and about 700 degrees Celsius or less. According to an embodiment, the vapor phase epitaxial growth process can be a low pressure CVD process occurring in about 650 degrees Celsius. The low pressure CVD process can reduce unwanted gas-phase reactions and improve film uniformity.

The doped semiconductor film, deposited through an in situ SEG process, such as a vapor phase epitaxial growth process, can have a thickness on the order of nanometers. According to an embodiment, the doped semiconductor film can have a thickness between about 1 nanometer and about 100 nanometers. According to another embodiment, the doped semiconductor film can have a thickness between about 20 nanometers and about 60 nanometers. In a further embodiment, the doped semiconductor film can have a thickness between about 35 nanometers and about 45 nanometers. According to another embodiment, the doped semiconductor film can have a thickness of about 40 nanometers.

The doped semiconductor film can have a dopant concentration of about 1×10²⁰ cm⁻³ or more. According to another embodiment, the doped semiconductor film can have a dopant concentration of about 1.5×10²⁰ cm⁻³ or more. In a further embodiment, the doped semiconductor film can have a dopant concentration of about 2×10²⁰ cm⁻³ or more.

The doped semiconductor film can be deposited on a semiconductor substrate. The resistivity of the substrate can be, according to an embodiment, about 1 Ωcm or more and about 25 Ωcm or less. According to another embodiment, the resistivity of the substrate can be about 5 Ωcm or more and about 20 Ωcm or less. In a further embodiment, the resistivity of the substrate can be between about 9 Ωcm or more and about 18 Ωcm or less.

At element 104, the doped semiconductor film can undergo an ion implantation process. In the ion implantation process, ions of a material can be accelerated in an electric field and impacted on the doped semiconductor film. Ion implantation can change the physical properties, chemical properties, mechanical properties, or the like, of the semiconductor film. The ions implanted in the doped semiconductor film can be silicon ions, germanium ions, or the like. The ions implanted in the doped semiconductor film can also be one or more of carbon ions, arsenic ions, and/or phosphorous ions. Ion energies utilized in the ion implantation process can be about 1 keV or more and about 20 keV or less. According to an embodiment, ion energies utilized in the ion implantation process can be about 2 keV or more and about 16 keV or less. Higher and/or lower energies can be used, depending on the type of ion, the thickness of the film, and the like.

Each individual ion in the ion implantation process can produce point defects in the crystalline structure of the doped semiconductor film. The point defects can include vacancies, interstitials, or the like. The point defects can migrate and cluster with each other, resulting in further defects.

Traditionally, ion implantation is performed in room temperature. This can lead to point defects and clustered point defects in the crystalline structure. Performing ion implantation in a lower temperature can reduce the point defects and clustered point defects in the crystalline structure. Accordingly, during the ion implantation of element 104, the doped semiconductor film can be maintained at a temperature less than room temperature to reduce the point defects or clustered point defects. According to an embodiment, the doped semiconductor film can be maintained at a temperature of zero degrees Celsius or less. According to another embodiment, the temperature of the doped semiconductor film can be maintained at a temperature of about −60 degrees Celsius or less. According to a further embodiment, the temperature of the doped semiconductor film can be maintained at a temperature of about −100 degrees Celsius or less.

The bombardment with ions during ion implantation tends to increase the temperature of the doped semiconductor film. The doped semiconductor film can be maintained in a low temperature by a mechanism that cools the doped semiconductor film. The mechanism can include a cooling device employing one or more cryogenic fluids, cryogenic gasses, or the like. With ion implantation conducted on a doped semiconductor film maintained in the temperature less than room temperature, the amount of crystallographic damage can be enough to completely amorphize the doped semiconductor film.

At element 106, after the ion implantation of element 104, the doped semiconductor film can be regrown through annealing. The annealing technique of element 106 can be a fast annealing technique, such as nonmelt laser annealing, flash lamp annealing, or the like. The annealing technique can be any annealing technique that can be done at a high temperature (e.g. about 1000 degrees Celsius or more) for a short time (e.g., about 10 milliseconds or less). Annealing at a high temperature for a short time can activate dopants in the doped semiconductor film, but can also minimize diffusion. The annealing process can be done at a temperature of about 1000 degrees Celsius or more. The annealing process can also be conducted at a temperature of about 1100 degrees Celsius or more and about 1300 degrees Celsius or less. The annealing process can be conducted at a temperature of about 1200 degrees Celsius or more and about 1225 degrees Celsius or less. The annealing process can be conducted for a time period of about 10 milliseconds or less. The annealing process can also be conducted for a time period of about 2 milliseconds or less. For example, heating the doped semiconductor film at about 1200 degrees Celsius a time of about 2 milliseconds or less can allow dopant activation above the solid solubility of the dopant in the semiconductor material.

According to an example, the doped semiconductor film can be a phosphorous doped silicon epitaxial grown film. Referring now to FIG. 2, illustrated is a schematic process flow diagram of an example method 200 for improving phosphorous activation efficiency and reducing crystalline defects in a silicon:phosphorous (Si:P) epitaxial grown film. At element 202, an in situ SEG can be employed to form the Si:P epitaxial grown film. The Si:P film can be grown on a silicon substrate. The in situ SEG can be a low pressure CVD process. The low pressure CVD process can employ dichlorosilane/hydrogen gas mixture with phosphine impurities. The low pressure CVD process can occur at a temperature of about 650 degrees Celsius. The Si:P epitaxial grown film is a silicon film including a phosphorous ion as an impurity.

The Si:P film can have a thickness on the order of nanometers. More specifically, the Si:P film can have a thickness of about 20 nanometers or more and about 50 nanometers of less. According to an embodiment, the Si:P film can have a thickness of about 35 nm or more and about 45 nanometers or less. In a further embodiment, the Si:P film can have a thickness of about 40 nanometers.

According to an embodiment, the concentration of phosphorous in the Si:P film can be about 1×10²⁰ cm⁻³ or more. According to another embodiment, the concentration of phosphorous in the Si:P film can be about 1.5×10²⁰ cm⁻³ or more. In a further embodiment, the concentration of phosphorous in the Si:P film can be about 2×10²⁰ cm⁻³ or more.

According to an embodiment, the substrate can be a p-type silicon substrate. The resistivity of the substrate can be, according to an embodiment, the resistivity of the substrate can be 9 Ωcm or more and about 18 Ωcm or less.

At element 204, the Si:P film can undergo an ion implantation process. During the ion implantation process, silicon ions can be accelerated in an electric field and impacted on the Si:P film. Ion energies utilized in the ion implantation process can be about 2 keV or more and about 16 keV or less. To reduce point defects in the crystalline structure of the Si:P film, the Si:P film can be maintained in a low temperature of about −60 degrees Celsius or less during the ion implantation process. The Si:P film can be maintained in a low temperature by a mechanism that cools the Si:P film. The mechanism can include a cooling device employing one or more cryogenic fluids, cryogenic gasses, or the like. With ion implantation in the low temperature, the amount of crystallographic damage can be enough to completely amorphize the Si:P film.

Ion implantation in temperatures of −60 degrees Celsius or less can facilitate high phosphorous activation activity and defect annihilation. TABLE I shows exemplary conditions for silicon ion (Si⁺) implantation in temperatures of −60 degrees Celsius or less.

TABLE 1
Exemplary conditions for cryogenic Si⁺ implantation in Si:P film.

| Energy | Fluence | Tile/Twist |
|---|---|---|
| 2.3 keV | 1 × 10¹⁵ cm⁻² | 0⁰/0⁰ |
| 2.3 keV | 2.3 × 10¹⁵ cm⁻² | 0⁰/0⁰ |
| 8 keV | 2.3 × 10¹⁵ cm⁻² | 0⁰/0⁰ |
| 15 keV | 1 × 10¹⁵ cm⁻² | 0⁰/0⁰ |
| 15 keV | 2.3 × 10¹⁵ cm⁻² | 0⁰/0⁰ |

At element 206, after the ion implantation of element 204, the Si:P film can undergo recrystallization annealing. According to an embodiment, the recrystallization annealing can be performed using nonmelt laser annealing with a temperature of about 1200 degrees or more for a time of 2 milliseconds or less. The annealing at a high temperature for a short time allows extremely rapid heating and cooling, so that a high phosphorous activation above the solid solubility of phosphorous in silicon can be achieved.

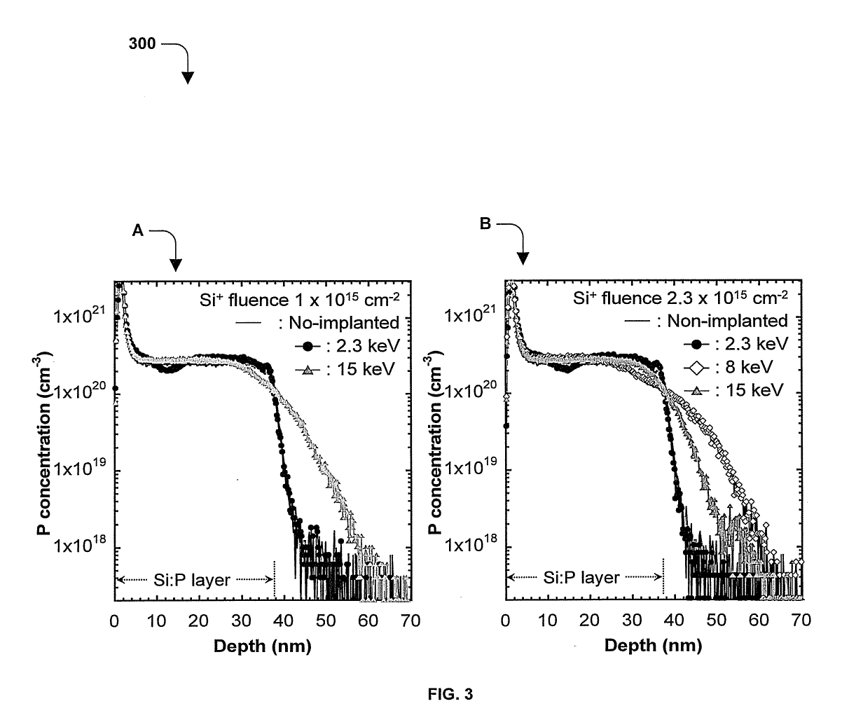

FIGS. 3-8 are provided to illustrate how method 200 can improve the phosphorous activation efficiency while reducing crystalline defects in the Si:P epitaxial film compared to conventional methods.

FIG. 3 shows depth profiles 300 of phosphorous in the cryogenically silicon ion implanted Si:P film with a fluence of 1×10¹⁵ cm⁻² (A) and 2.3×10¹⁵ cm⁻² (B) after laser annealing at 1225° C. for 2 milliseconds or less. The depth profiles 300 of FIG. 3 were measured by secondary-ion mass spectroscopy (SIMS) with Cs⁺ as the primary ion at a sputter energy of 500 eV.

In the depth profiles 300, the solid line indicates phosphorous profiles of non-implanted samples. Phosphorous diffusion varies depending on implantation condition. No marked changes in phosphorous depth profiles are clearly observed in the nonmelt laser annealed samples without cryogenic silicon ion implantation. The nonmelt laser annealing allowed extremely rapid heating and cooling within a few milliseconds, so that phosphorous atoms could not be moved. In contrast, silicon ion implantations at 8 keV and 15 keV at a temperature of −60 degrees Celsius or less permit an increased amount of phosphorous diffusion during laser annealing at about 1225 degrees Celsius.

In addition, with cryogenic silicon ion implantation at 8 keV, as shown in FIG. 3(B), the phosphorous profile at a concentration of about 1.5×10²⁰ cm⁻³ shows a deeper diffusion profile, which can be due, for example, to ion implantation damage induced transient enhanced diffusion of phosphorous atoms via self-interstitial silicon atoms during nonmelt laser annealing within less than 2 milliseconds. In contrast, the sample implanted at 15 keV shows a shallow phosphorous diffusion profile compared with the sample implanted at 8 keV, as shown in FIG. 3(B). By considering a difference in excess self-interstitial silicon distribution created by cryogenic silicon ion implantation and Si:P thickness, since the excess self-interstitial silicon distribution is moved away from the phosphorous profile by increasing the implantation energy, it is likely to result in less enhanced phosphorous diffusion.

The phosphorous profile near the Si:P/Si substrate interface for the shallowest implanted (2.3 keV) samples remain the same compared to the non-implanted samples. In addition, the phosphorous plateau profile changes its undulation at a depth deeper than about 10 nanometer, so, since the excess self-interstitial silicon atoms produced by the shallow implantation are not distributed sufficiently to nearby the Si:P/Si substrate interface, diffused phosphorous atoms via excess self-interstitial silicon atoms cannot move beyond the interface during the nonmelt laser annealing within about 2 milliseconds or less.

With silicon ions implantations in temperatures of −60 degrees Celsius or less at 8 and 15 keV, phosphorous atoms are diffusing toward Si substrate. As shown in FIG. 3, inactive phosphorous atoms in the Si:P epitaxial grown film are activated efficiently by the silicon ion implantation in −60 degrees Celsius or less and nonmelt laser annealing recrystallization at 1200 degrees Celsius or more for a time period of 2 milliseconds or less.

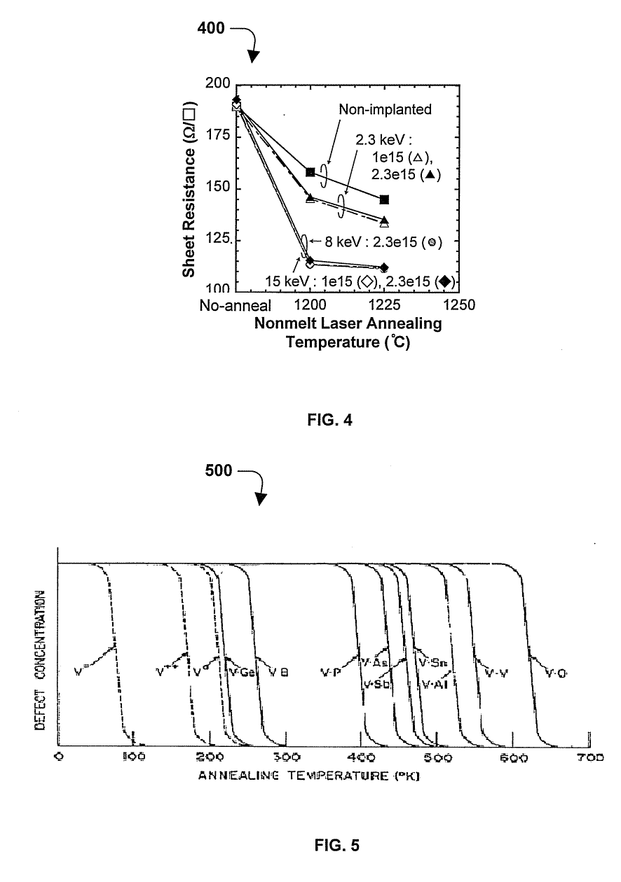

FIG. 4 shows electrical characteristics 400 of a Si:P epitaxial grown film that has undergone silicon ion implantation at a temperature of −60 degrees Celsius or less and laser annealing recrystallization. Electrical conductivity of silicon ion implanted Si:P film varies depending on silicon ion implantation energy and/or nonmelt laser annealing temperature.

The electrical properties of the Si:P film were evaluated by a linear four-point probe (4PP) method. FIG. 4, illustrates the effect of silicon ion implanted Si:P film with a fluence of about 1×10¹⁵ cm⁻² or more after laser annealing recrystallization at about 1200 degrees Celsius or more and about 2 milliseconds or less on sheet resistance. The sheet resistance of a non-implanted sample decreases with increasing annealing temperature.

Meanwhile, the amount of reduction in sheet resistance increases with silicon ion implantation in temperatures of −60 degrees Celsius or less.

The difference between the sheet resistance of as-grown Si:P versus the Si:P annealed at 1225 degrees Celsius laser annealing is about 22 percent. This can be interpreted in terms of a thermal decomposition of inactive phosphorous-containing clusters and precipitates and resultant activation of phosphorous atoms during laser annealing at a temperature of about 1200 degrees Celsius or more.

The amount of reduction in the sheet resistance increases by the silicon ion implantation in temperatures of about −60 degrees Celsius or less. An about 6 percent sheet resistance decrease is observed in the 2.3 keV cryogenic silicon ion implanted samples in comparison with the non-implanted samples after laser annealing at about 1225 degrees Celsius.

While the 2.3 keV silicon ion implantation in −60 degrees Celsius or less has no effect on phosphorous diffusion toward the silicon substrate for any annealing temperature, silicon ion implantations at a temperature of −60 degrees Celsius or less at energies of 8 keV and 15 keV show a marked decrease in sheet resistance as phosphorous atoms are diffusing toward the silicon substrate. The sheet resistance of the 15 keV cryogenic silicon ion implanted samples is the same compared to the 8 keV cryogenic silicon ion implanted samples. By considering the phosphorous profile shown in FIG. 3(B), the 15 keV silicon ion implantation is likely to increase a number of active phosphorous atoms compared to the 8 keV silicon ion implantation, which can be interpreted in terms of a thick amorphous Si:P created by the high energy silicon ion implantation. These results indicate that inactive phosphorous atoms in the Si:P epitaxial grown film are activated efficiently by the silicon ion implantation in temperatures of −60 degrees Celsius or less and nonmelt laser annealing recrystallization at about 1200 degrees Celsius or more for 2 milliseconds or less.

FIG. 5 shows a plot 500 of defect concentration for different annealing temperatures. As shown in FIG. 5, the probability of different types of vacancies in silicon is strongly dependent ion implantation temperature. In usual high-current ion implanters, silicon substrate temperature is controlled less than 60 degrees Celsius by cooling the silicon substrate with flowing water in the wafer suscepter. However, various types of single vacancies, such as V²⁻, V⁻, V⁰, V⁺, and V²⁺, cannot exist at such a high temperature. Therefore, the vacancy binds with another vacancy or impurity atom, such as oxygen.

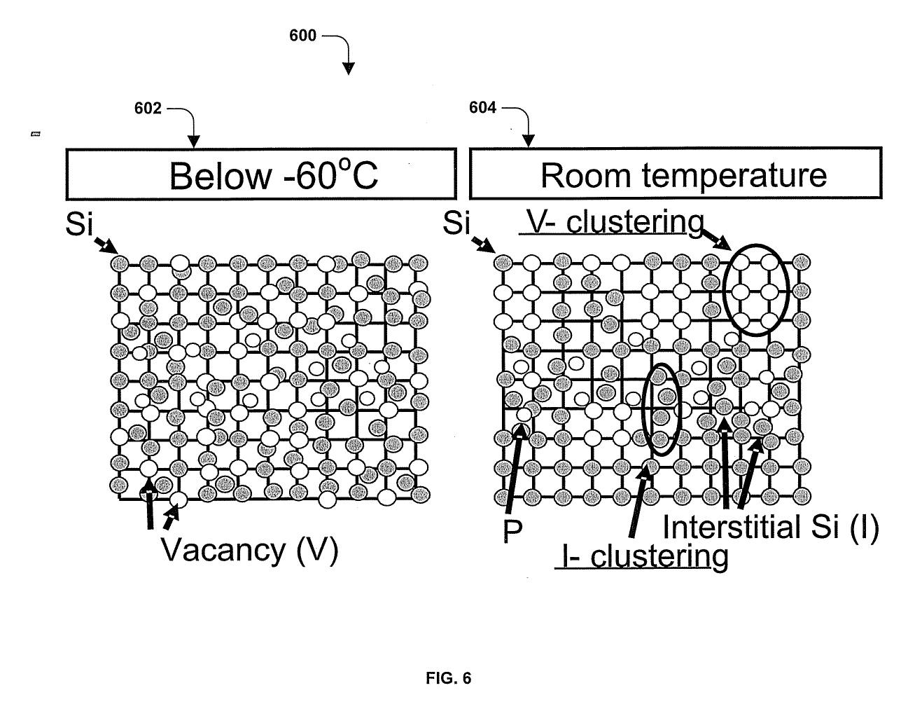

FIG. 6 shows a schematic illustration 600 of the difference in defect density during ion implantation in different temperatures. Element 602 shows the effect of ion implantation in temperatures of about −60 degrees Celsius or less. Element 604 shows the effect of ion implantation in room temperature. Element 604 shows clustering of point defects, such as interstitial silicon clustering and vacancy clustering. In contrast, element 602 shows suppression of clustering of point defects, including both interstitial silicon clustering and vacancy clustering.

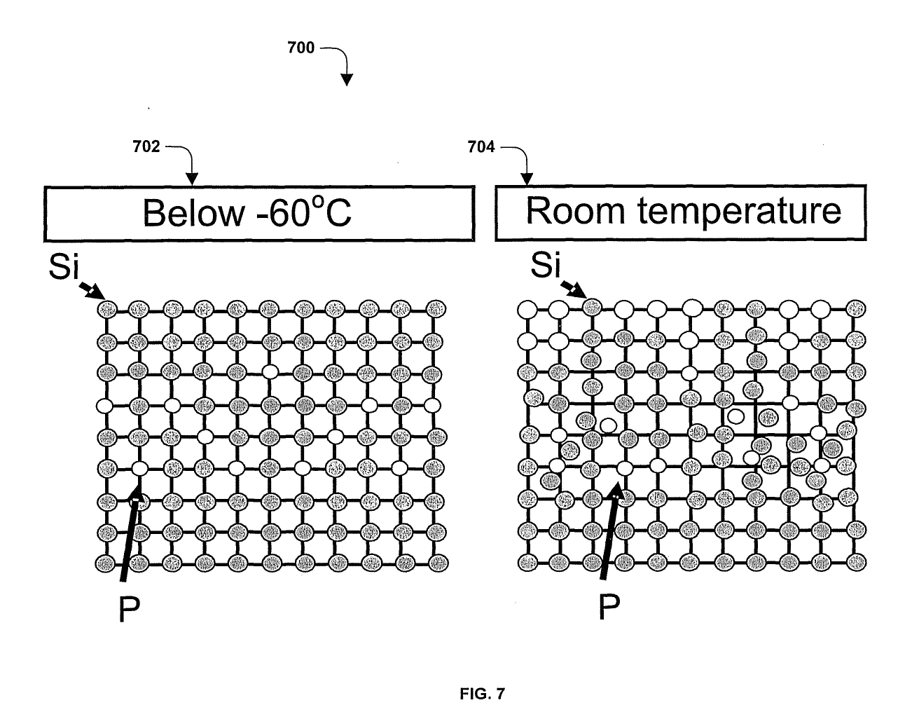

FIG. 7 shows a schematic illustration 700 of the difference in defect density after annealing. Element 702 shows the effect of ion implantation in temperatures about −60 degrees Celsius or less. Element 704 shows the effect of ion implantation in room temperature. In comparing element 702 and element 704, it is clear that defect annihilation and high phosphorous activation can be achieved by ion implantation in temperatures of about −60 degrees Celsius or less.

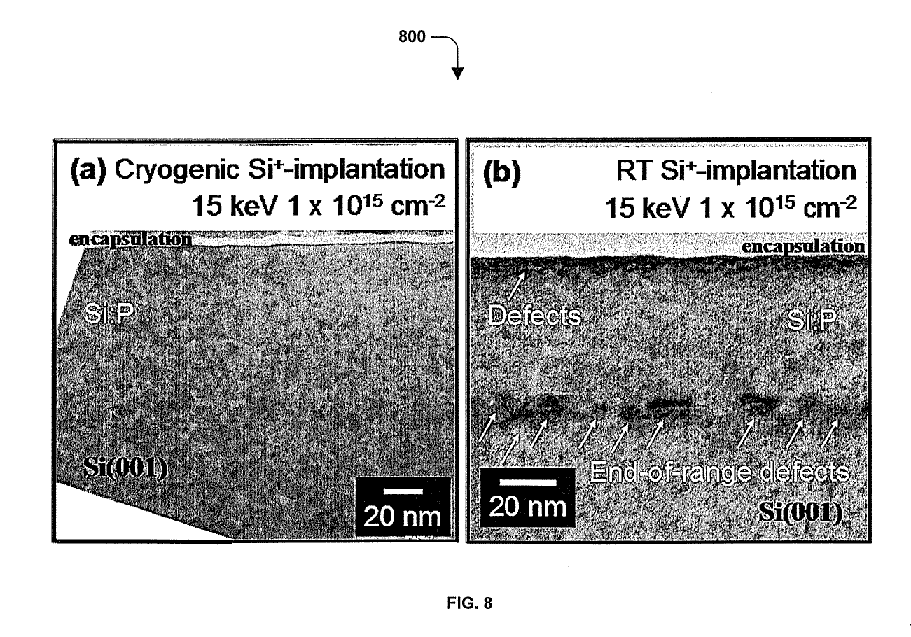

Ion implantation in temperatures of −60 degrees Celsius or less can reduce the number of residual crystal defects after annealing and due to rapid amorphization and suppression of both silicon interstitial clustering and vacancy clustering. Referring now to FIG. 8, illustrated are cross sectional transmission electron microscopy images 800 showing crystal quality on the surface of Si:P films.

Shown in FIG. 8 are samples after silicon ion implantation with a fluence of 1×10¹⁵ cm⁻² after laser annealing in 1225 degrees Celsius. No crystal defects can be observed in the sample that has undergone silicon ion implantation at a temperature of about −60 degrees Celsius or less (A). However, in the room temperature silicon ion implanted sample (B), many residual crystal defects can be observed, such as dislocations, stacking faults, and end-of-range defects.

Accordingly, as described herein with respect to FIGS. 3-8, high Si:P epitaxial growth temperature (about 675 degrees Celsius or more) reduces activation efficiency of phosphorous doping, but also increases the growth rate, which can be due to clustering and/or precipitates of phosphorous atoms by the high temperature. Silicon ion implantation with a fluence of about 1×10¹⁵ cm⁻² at a temperature of about −60 degrees Celsius or less can reduce the number of residual crystal defects after laser annealing at about 1225 degrees C. for about 2 milliseconds or less.

Additionally, phosphorous diffusion via point defects after nonmelt laser annealing at a temperature of about 1200 degrees Celsius or more for a time of 2 milliseconds or less can vary depending on the silicon ion implantation energy when ion implantation occurs in temperatures of −60 degrees Celsius or less. This can be interpreted in terms of the Si:P grown thickness and excess self-interstitial silicon distribution created by the silicon ion implantation at a temperature of −60 degrees Celsius or less. Accordingly, heavy silicon ion implantation at a temperature of −60 degrees Celsius or less with a fluence higher than 1×10¹⁵ cm⁻² followed by nonmelt laser annealing at a temperature of 1200 degrees Celsius or more for a time of 2 milliseconds or less successfully activates inactive phosphorous ions in the Si:P film.

To achieve these benefits, according to an embodiment, a Si:P film can be ion implanted with silicon ions at a temperature of about 60 degrees Celsius or less with a fluence of about 1×10¹⁵ cm⁻² or more. After the ion implantation, the Si:P film can undergo nonmelt laser annealing at a temperature of 1200 degrees Celsius or more for a time of 2 milliseconds or less.

Other than in the operating examples, or where otherwise indicated, all numbers, values and/or expressions referring to quantities of ingredients, reaction conditions, etc., used in the specification and claims are to be understood as modified in all instances by the term “about.”

With respect to any figure or numerical range for a given characteristic, a figure or a parameter from one range may be combined with another figure or a parameter from a different range for the same characteristic to generate a numerical range.

While certain embodiments have been described, these embodiments have been presented by way of example only, and are not intended to limit the scope of the inventions. Indeed, the methods and devices described herein can be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the subject innovation.

What is claimed is:

1. A method for increasing dopant activation efficiency in a doped silicon film, comprising:
forming a doped silicon film with a peak dopant concentration of 1×10²⁰ cm⁻³ or more;
amorphizing the doped silicon film through ion implantation; and
annealing the doped silicon film.

2. The method of claim 1, wherein forming the doped silicon film comprises an epitaxial growth process.

3. The method of claim 1, wherein forming the doped silicon film comprises a vapor phase epitaxial growth process.

4. The method of claim 3, wherein forming the doped silicon film comprises using a gas with a mixture of SiH₂Cl₂/H₂ in the vapor phase epitaxial growth process.

5. The method of claim 1, wherein forming the doped silicon film comprises using at least one of boron, arsenic or phosphorous as a dopant.

6. The method of claim 1, wherein the amorphizing comprises ion implantation at a temperature of about −60 degrees Celsius or lower.

7. The method of claim 1, wherein annealing the doped silicon film is conducted at a temperature from about 1100 degrees Celsius or more to about 1300 degrees Celsius or less.

8. The method of claim 1, wherein annealing the doped silicon film is conducted for a time period of about 10 milliseconds or less.

9. The method of claim 1, wherein annealing the doped silicon film is conducted for a time period of about 2 milliseconds or less.

10. A method of making a source/drain structure for a transistor, comprising:
forming a doped silicon film with a peak dopant concentration of 1×10²⁰ cm⁻³ or more using an epitaxial growth process;
implanting silicon ions in the doped silicon film at a temperature of about 0 degrees Celsius or less; and
annealing the doped silicon film for a time period of about two milliseconds or less.

11. The method of claim 10, wherein implanting silicon ions in the doped silicon film is conducted at a temperature of about −60 degrees Celsius or less.

12. The method of claim 10, wherein forming the doped silicon film comprises using at least one of arsenic, boron or phosphorous.

13. The method of claim 10, wherein forming the doped silicon film is conducted at a temperature of about 600 degrees Celsius or greater.

14. The method of claim 10, wherein annealing the doped silicon film is conducted at a temperature of about 1100 degrees Celsius or greater and about 1300 degrees Celsius or less.

15. The method of claim 10, wherein annealing comprises at least one of nonmelt laser annealing or flash lamp annealing.

16. A method for reducing crystal defects in a doped silicon epitaxial film, comprising:
performing silicon ion implantation on the doped silicon epitaxial film at a temperature of about 0 degrees Celsius or less; and
annealing the doped silicon epitaxial film at a temperature of about 1100 degrees Celsius or more and about 1300 degrees Celsius or less for about 10 milliseconds or less.

17. The method of claim 16, further comprising annihilating defects in the doped silicon epitaxial film based on at least one of the performing the silicon ion implantation or the annealing.

18. The method of claim 16, wherein the doped silicon epitaxial film is a phosphorous doped silicon epitaxial film.

19. The method of claim 16, wherein annealing the doped silicon epitaxial film is conducted at a temperature from about 1200 degrees Celsius or more to about 1225 degrees Celsius or less.

20. The method of claim 16, wherein performing silicon ion implantation on the doped silicon epitaxial film is conducted at a temperature of about −60 degrees Celsius or less.
